(19) United States
(12) Patent Application Publication
(10) Pub. No.: US 2005/0069142 A1
(43) Pub. Date: Mar. 31, 2005

(54) Integrated circuit and electronic apparatus provided with the same with software IP implementation

(76) Inventors: Shigeki Mabuchi, Ukyo-Ku (JP); Masanori Fujisawa, Ukyo-Ku (JP)

Correspondence Address: CANTOR COLBURN LLP, 55 Griffin Road South, Bloomfield, CT, 06002, US

(21) Appl. No.: 10/950,093

(22) Filed: Sep. 24, 2004

(30) Foreign Application Priority Data
Sep. 25, 2003 (JP) JP2003-334446

(51) Int. Cl. G06F 15/00; G06F 15/76; H03G 3/00

(52) U.S. Cl. 381/61; 712/34

(57) ABSTRACT

A main function unit is an IP that implements by hardware main functions selected from a group of functions provided by an integrated circuit. A sub-function unit implements by software some of the group of functions provided by the integrated circuit. A process managing unit responds to an external signal and directs at least the sub-function unit to perform a process.

### BACKGROUND OF THE INVENTION

1. Field of the Invention

The present invention relates to integrated circuits and electronic apparatuses and, more particularly, to an integrated circuit providing a group of functions and an electronic apparatus provided with such an integrated circuit.

2. Description of the Related Art

Electronic apparatuses such as portable telephones, personal digital assistants, personal computers and CD players have become widely available. While the performance of these apparatuses has been boosted year by year, they have also been reduced in size and weight. Lying in the background of the simultaneously proceeding size reduction and performance improvement, which are basically contradictory to each other, are advances in semiconductor technology.

Historically, an important factor behind this is the fact that the processing speed of a central processing unit has doubled periodically in the past. Since the level of high integration implemented only by CPUs is limited, there has been created a concept called “system on a chip” (SoC) whereby not only a CPU but also the entirety of functions of an electronic apparatus, including an I/O circuit etc., is build on a chip. In this background, there has been an expansion in IP business, in which functional blocks constituting an extremely highly integrated circuit such as SoC are prepared so that a variety of user's needs are efficiently met by re-using the blocks or combining the same. IP stands for intellectual properly and is an expression which focuses on a circuit implementing a functional block as an intellectual property. IP is an important asset for an LSI manufacturer by helping a product from that manufacturer to be employed by a set manufacturer.

What makes IP business stand out from the conventional LSI business is that licenses are provided block by block. In a majority of cases, a license fee is built unnoticed into the cost of an LSI. One conceivable approach for an LSI manufacturer is to license a custom developed IP built into an LSI targeted for the set manufacturer as an intellectual property of its own. Naturally, a license fee will be determined by the market mechanism. [patent document No. 1] Japanese Laid-Open Patent Application No. 8-36558

While IPs fulfill functions independent from each other in many cases, some functions are related to each other. For example, related to the main sound source function in a sound source LSI are surround functions etc. By building a whole set of related functions into an LSI, the LSI manufacturer is capable of promoting products that are richer in functions. A set manufacturer may not know, however, whether the whole set of related functions are necessary while a product is being developed, particularly in an initial stage of development. Implementing the whole of related IPs in an LSI just for the purpose of promoting multiple functions places an LSI manufacturer in an unfavorable position in terms of license fee, aside from the fact that the chip area is wasted. The problems as discussed above may cause a set manufacturer to hesitate to exploit IPs and ultimately affect the business of the LSI manufacturer.

### SUMMARY OF THE INVENTION

The present invention has been done in view of these circumstances and its object is to provide a technology for adapting to requirements of a set manufacturer flexibly and a technology for efficiently preventing unused IPs from being implemented.

One mode of the present invention is an integrated circuit implementing predetermined functions. The integrated circuit comprises: a main function unit implementing by hardware predetermined functions selected from a group of functions provided by the integrated circuit; a sub-function unit storing programs implementing functions other than the predetermined function by software; and a process managing unit responding to an external instruction and activating a process at least using the sub-function unit, wherein the process managing unit receives the instruction in the format which assumes that the sub-function unit is constructed of hardware. With this, the integrated circuit is controllable on an assumption that the entirety of the integrated circuit is hardware implemented. That is, the process managing unit does away with an apparent difference between hardware and software, regardless of how the hardware and software are assigned to respective functions inside the integrated circuit. The predetermined functions may be main functions of the integrated circuit and functions other than the predetermined functions may be optional functions. A group of functions is a combination of various processing functions in a specific field of information processing. For example, sound source related functions, speech processing related functions or image processing related functions may constitute a group.

The integrated circuit further comprises a CPU, wherein the process managing unit activates the CPU when it is determined that the external instruction requires a process using the sub-function unit. With this, functions are implemented both by hardware and software inside the integrated circuit so that the handling is made easy.

The CPU may convert the external instruction into address information and reads a program stored in the sub-function unit.

The process managing unit may activate an external unit so as to allow an external processing agent to execute the process using the sub-function unit. With this, it is possible to activate software implemented functions using a CPU, for example, located outside the integrated circuit.

Another mode of the present invention is also an integrated circuit implementing predetermined functions. The integrated circuit comprises: a main function unit implementing by hardware predetermined functions selected from a group of functions provided by the integrated circuit; a sub-function unit storing programs implementing functions other than the predetermined function by software; and a conversion process mechanism converting an external instruction into information for a predetermined processing agent to read a program stored in the sub-function unit, when the external instruction requires a process using the sub-function unit.

The external instruction may include an instruction that directly operates hardware such as an “OUT command”.

Optional combinations of the aforementioned constituting elements, and implementations of the invention in the form of methods, apparatuses, systems, recording mediums and computer programs may also be practiced as additional modes of the present invention.

According to the present invention, semiconductor integrated circuits provided with functions that meet customer needs are flexibly provided in response to customer needs.

### BRIEF DESCRIPTION OF THE DRAWINGS

FIG. 1 shows an internal construction of an integrated circuit according to a first embodiment of the present invention.

FIG. 2 shows a construction of hardware of the integrated circuit of FIG. 1.

FIG. 3 is a flowchart showing an interrupt handler.

FIG. 4 shows a data structure in a memory of FIG. 2.

FIG. 5 shows a data structure of availability information

FIG. 6 shows a data structure in a table of FIG. 4.

FIG. 7 shows an internal construction of an electronic apparatus in which the integrated circuit described by referring to FIGS. 1 and 2 is installed.

FIG. 8 shows an internal construction of the integrated circuit according to a second embodiment of the present invention.

FIG. 9 shows a sequence of operation in the main CPU and the integrated circuit when the integrated circuit of FIG. 8 is built into the electronic apparatus of FIG. 7.

FIG. 10 shows an overall work flow observed before the integrated circuit according to the first embodiment or the second embodiment is shipped to a set manufacturer.

### DETAILED DESCRIPTION OF THE INVENTION

First Embodiment

In the integrated circuit according to the first embodiment, IPs which may or not may not be utilized by a set manufacturer ultimately are implemented by software. With this, an LSI manufacturer is capable of adapting to requirements of a set manufacturer flexibly and promptly. Further, the license fee for unused IPs is prevented from being incurred, thereby reducing the ultimate cost. There are a variety of combinations in which software and hardware are combined. Generating a control program for each and every combination will result in poor efficiency in development. The embodiment provides a technology whereby an integrated circuit in which predetermined functions are implemented in the form of a combination of hardware and software is controlled by a single control program.

A prerequisite for achieving this purpose is that functions that may possibly be implemented by software are controlled by the same procedure, i.e. the same control program, as the IP implemented by hardware. More specifically, a control program directed to hardware is converted in an integrated circuit into a program adapted to software. The LSI manufacturer might want to license functions implemented by software as the case may be. By deleting software corresponding to functions determined not to be used ultimately from the memory of the integrated circuit, it is ensured that at least the license fee for the deleted functions is not incurred.

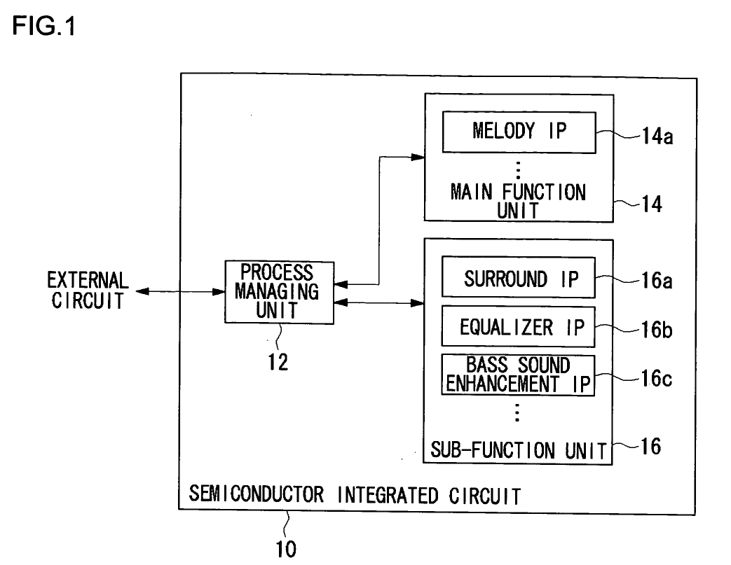

FIG. 1 shows an internal construction of a semiconductor integrated circuit device 10 (hereinafter, simply referred to as the integrated circuit 10) according to the first embodiment. The integrated circuit 10 is implemented primarily by means of a CPU, IPs, a memory and programs loaded into the memory. It will be obvious to those skilled in the art that there are a variety of implementation methods and hardware structures. FIG. 1 shows a construction including function units.

A main function unit 14 is a hardware block of IPs (hereafter, simply referred to as hardware IPs) implementing primary functions provided by the integrated circuit 10. In this embodiment, a melody IP 14a is installed as the hardware IP. Preferably, a primary function is a function used without exception or a function that places so heavy a load on the CPU (not shown) that defies software processing. The function may be determined according to demands from the set manufacturer or determined by the LSI manufacturer. A single hardware IP or a plurality of hardware IPs may be installed in the integrated circuit 10.

A sub-function unit 16 contains IPs implementing optional functions provided by the integrated circuit 10. The sub-function unit 16 actually stores programs. An IP implemented by software will be referred to as a software IP. In this embodiment, a surround IP 16a, an equalizer IP 16b and a bass sound enhancer IP 16c are installed in the sub-function unit 16. In this embodiment, the integrated circuit 10 as a sound source will be described. Alternatively, various other functions such as image processing, communications processing and speech recognition processing may be installed in the integrated circuit 10. The sub-function unit 16 may provide the same function as installed in the main function unit 14. Alternatively, it may be ensured that functions do not overlap. Given that similar functions are installed both in the main function unit 14 and the sub-function unit 16, the main function unit 14 and the sub-function unit 16 are capable of performing the same process simultaneously since the CPU (not shown) implementing the sub-function unit 16 and the main function unit 14 operate independently of each other.

A process managing unit 12 receives an instruction from an external circuit in the format which assumes that the sub-function unit 16 is constructed of hardware, and activates a process at least using the sub-function unit 16. That is, the process managing unit 12 does away with an apparent difference between hardware and software, regardless of how the hardware and software are assigned to respective functions inside the integrated circuit 10. With this, the external circuit 10 is capable of controlling the integrated circuit 10 on an assumption that the entirety of the integrated circuit is hardware implemented. That is, only one control program is necessary to control the integrated circuit 10.

By implementing optional functions by software, the LSI manufacturer is capable of reducing a period of time required for manufacturing the integrated circuit 10 and shipping the integrated circuit 10 in which only those functions needed by the set manufacturer are installed. Consequently, the license fee for unused hardware IP is prevented from being incurred so that the cost of the integrated circuit 10 is reduced. This will ultimately lower the cost of an electronic apparatus in which the integrated circuit 10 is installed.

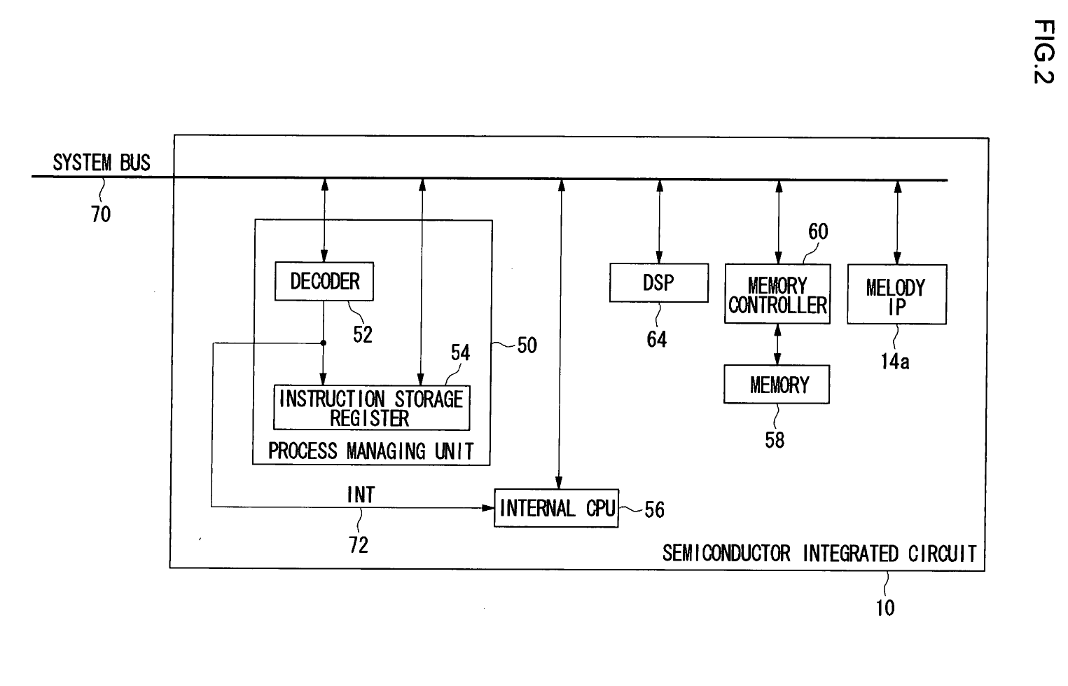

FIG. 2 shows a construction of hardware of the integrated circuit 10 of FIG. 1. A system bus 70 transmits addresses, data, R/W commands and status signals (hereinafter, these signals will be generically referred to as bus signals) from the CPU (not shown and hereinafter referred to as the external CPU) of the electronic apparatus in which the integrated circuit 10 is installed to the integrated circuit 10. Each IP in the integrated circuit 10 performs a predetermined function by writing data in a predetermined register. For this purpose, the external CPU generates a write cycle and outputs addresses and data for operating a desired IP to the system bus 70. Accordingly, the data are written in the register so that the IP is operated. For example, given that the address of the register for the melody IP 14a is 1400h, the melody IP 14a is operated by the external CPU writing predetermined data in the register at the address 1400h.

Regardless of whether an IP for a predetermined process is implemented by hardware or software in the integrated circuit 10, the IP accepts an instruction for operation at a common register. With this construction, a desired process is available to the external CPU only by writing data in the register. In other words, it is possible to handle the integrated circuit 10 by a single control program regardless of the combination of hardware IP and software IP in the integrated circuit 10.

The process managing unit 50 is provided with a decoder 52 and a instruction storage register 54 and directs an internal CPU 56 inside the integrated circuit 10 to activate the software IP in accordance with an address and data on the system bus 70. The decoder 52 identifies addresses and data directed to respective IPs including hardware IP and software IP implemented in the integrated circuit 10, and outputs a hit signal to the register 54. The decoder 52 also outputs the hit signal as an interrupt signal 72 to the internal CPU 56. The instruction storage register 54 temporarily stores the address and data on the system bus 70 when it receives the hit signal from the decoder 52. The instruction storage register 54 temporarily stores the address and data for a selected IP implemented in the integrated circuit 10.

The internal CPU 56 reads an interrupt handler corresponding to the interrupt signal 72 from the memory 58 via a memory controller 60 and runs the handler. Specific processes performed by the interrupt handler will be described later. By running the interrupt handler, the internal CPU 56 determines whether a software IP or a hardware IP is used. When the function is implemented by the software IP, the internal CPU 56 reads a program for activating the software IP from the memory 58. When the function is implemented by the hardware IP, the internal CPU 56 stands by to accept a next interrupt signal 72. At this point of time, the hardware IP is already starting a process in accordance with the data written in the register assigned to that IP.

The memory 58 is a generic reference to a ROM storing a program required by the internal CPU 56, a RAM used by the internal CPU 56 as a work area, and the like. In an alternative embodiment, the ROM and the RAM may be provided separately. The memory controller 60 writes or reads data in the address provided thereto via the system bus 70. A digital signal processor (DSP) 64 may be operated in accordance with an instruction from the internal CPU 56 or a bus signal from the external CPU. In an alternative embodiment, the DSP 64 may not be installed in the integrated circuit 10.

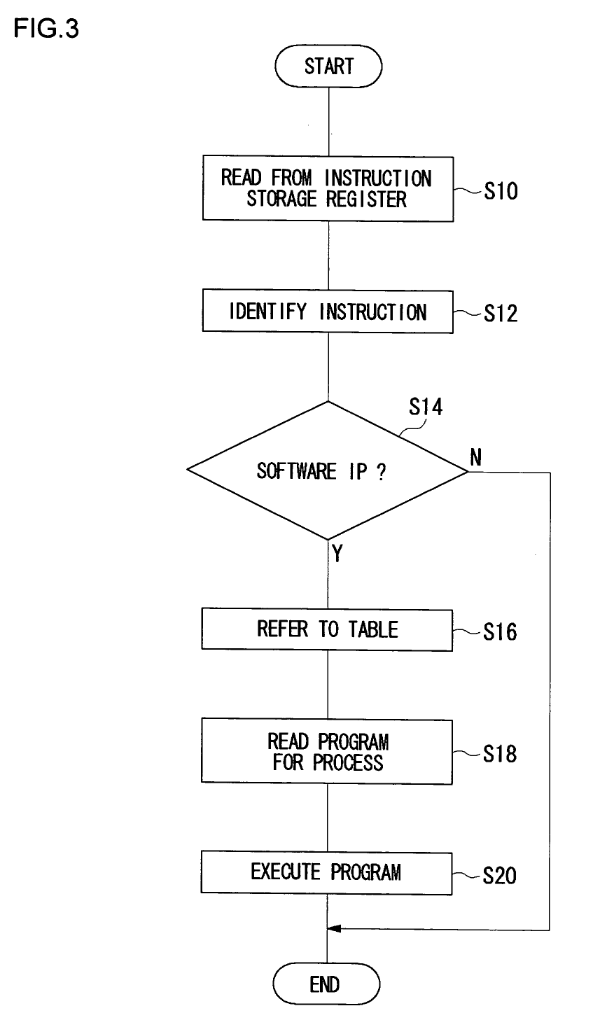

FIG. 3 shows a flowchart of the interrupt handler. The interrupt handler is stored in the memory 58 of FIG. 2. The internal CPU 56 of FIG. 2 runs the interrupt handler when it accepts the interrupt signal 72. In an interrupt process responsive to the interrupt signal 72, the internal CPU 56 reads the address and data stored in the instruction storage register 54 of FIG. 2 (S10). Subsequently, the CPU 56 identifies an IP to which the instruction is directed and also identifies the type of instruction, on the basis of the address and data thus read (S12). More specifically, the internal CPU 56 identifies the IP to be activated, on the basis of the address in the register corresponding to the IP, and identifies the type of instruction, on the basis of the data stored in the register.

The internal CPU 56 determines whether the IP thus identified is a software IP or a hardware IP according to a method described later (S14). If a software IP is identified (Yin S14), the internal CPU 56 refers to a table holding an address at which the program implementing the software IP is stored (S16) and reads the program from that address (S18). The internal CPU 56 then runs the program (S20) . Thus, a software IP is activated in accordance with an instruction compatible with hardware. When a hardware IP is identified in S14 (N in S14), the internal CPU 56 terminates the execution of interrupt handler. At this point of time, the hardware IP is already starting a process in accordance with the data written in the register assigned to that IP.

To summarize, the decoder 52 of FIG. 2 identifies an address and data on the system bus 70 directed to an IP installed in the integrated circuit 10 and outputs an interrupt signal 72 to the internal CPU 56 whenever a hit occurs. The internal CPU 56 determines whether an instruction is directed to a software IP or a hardware IP, on the basis of the address. If a software IP is to be activated, the internal CPU 56 reads a program from the memory 58 and runs the program. If the instruction is directed to a hardware IP, the internal CPU 56 terminates the execution of interrupt handler and places itself in a standby state. The hardware IP, independent of the internal CPU 56, executes its own process in accordance with the data written in the register assigned to the hardware IP.

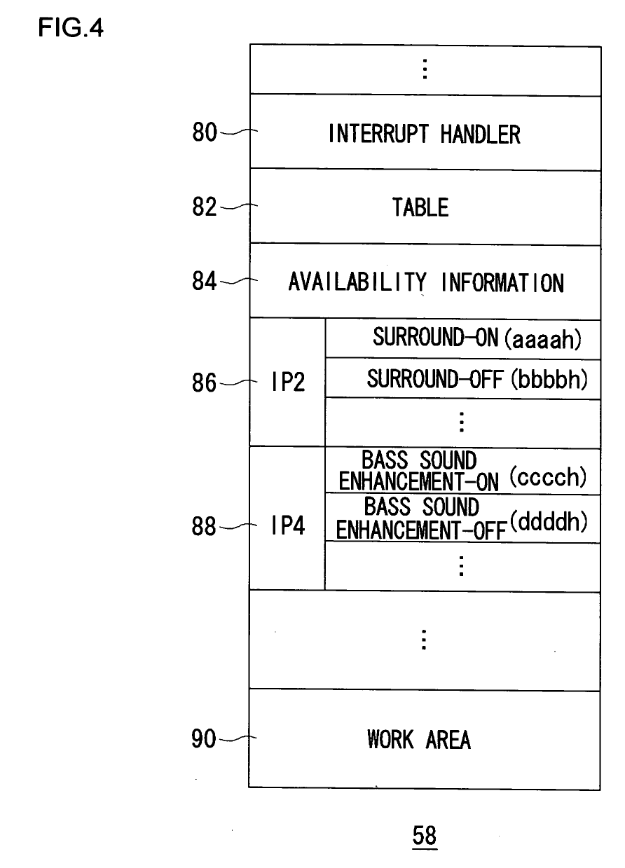

FIG. 4 shows a data structure in the memory 58 of FIG. 2. The interrupt handler 80 is an interrupt handler corresponding to the interrupt signal 72. A table 82 stores addresses at which programs implementing software IPs are stored. The data structure of the table 82 will be described later. Availability information 84 is information indicating whether a specific IP is available in the integrated circuit 10 and a mode of implementation, i.e. indication of whether the IP available is a hardware IP or a software IP. The data structure of the availability information 84 will be described later.

A first program 86 is a program implementing a software IP. In this figure, programs related to a “surround” IP are stored as the first program 86. There are a plurality of programs related to the surround IP a program for turning the surround function on is stored at “aaaah” and subsequent addresses, and a program for turning the surround function off is stored at “bbbbh” and subsequent addresses. Similarly, programs implementing a bass sound enhancement IP are stored as a second program 88. A work area 90 is a memory area used by the internal CPU 56 as required.

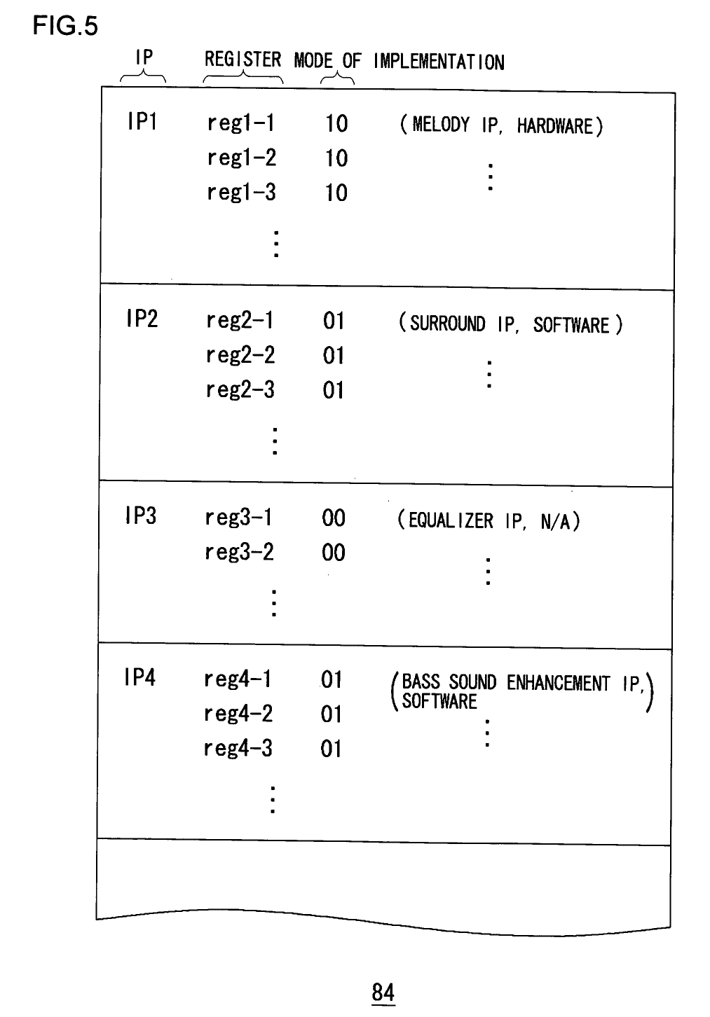

FIG. 5 shows a data structure of the availability information 84. Information identifying an IP, a register assigned to the IP and the mode of implementation of the IP are stored as the availability information 84. For brevity, registers are denoted by a notation such as “reg1-1”. The availability information actually stores addresses for respective registers. The mode of implementation information indicates whether an IP is available as a hardware implemented IP, a software implemented IP or not implemented. For example, the mode of implementation information is represented by 2 bits. In the illustration, “10” indicates that an IP is available as a hardware implemented IP. “01” indicates that an IP is available as a software implemented IP. “00” indicates that an IP is not implemented.

Steps S12 through S14 of FIG. 3 for identifying the mode of implementation of IP are performed by comparing the availability information 84 described by referring to FIG. 5 with the address read from the instruction storage register 54 of FIG. 2. For example, when the address “reg4-1” is stored in the instruction storage register 54, the internal CPU 56 refers to the availability information 84 using “reg4-1” as a search key and identifies the IP4 corresponding to the register at “reg4-1” as a software IP by detecting “01”.

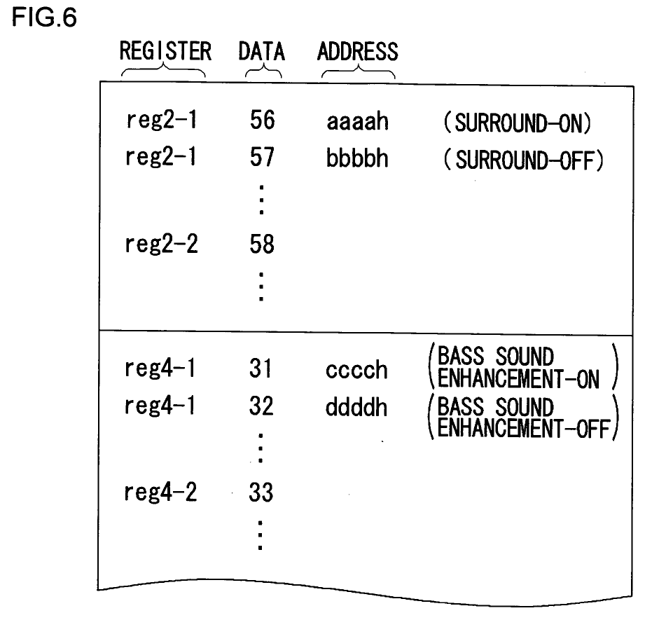

FIG. 6 shows a data construction of the table 82 of FIG. 4. The table 82 stores, for each register, data and address at which the program is stored. For example, the illustrated table shows that, when “56” is written as data in the register “reg2-1” for accepting an instruction for activation, the “surround-ON” process is performed, regardless of whether the IP for the surround process is implemented as a software IP or a hardware IP. In the example of FIG. 6, the surround IP is not implemented by hardware so that there is specified a start address “aaaah” indicating the location at which the program implementing the software IP is stored.

Steps S16 through S20 of FIG. 3 for implementing the software IP are performed, on the basis of the table 82 described by referring to FIG. 6, and the instruction-related information read from the instruction storage register 54 of FIG. 2. When “56” is written as data in the register “reg2-1”, the internal CPU 56 of FIG. 2 reads the program form the address “aaaah” of the memory 58 of FIG. 2 so as to execute the surround process using the software IP.

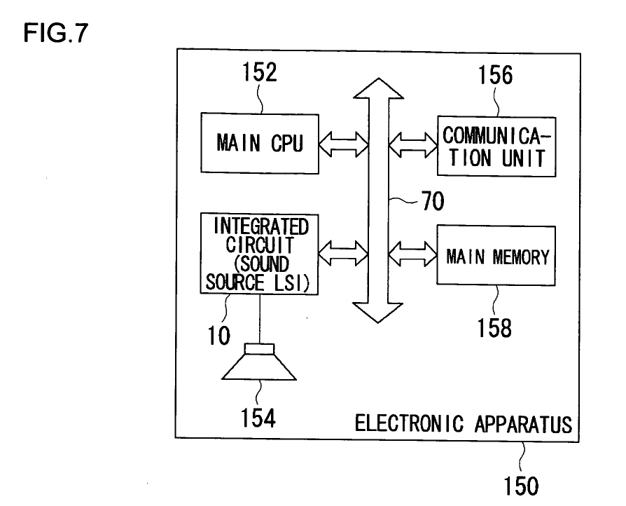

FIG. 7 shows an internal construction of an electronic apparatus 150 in which the integrated circuit 10 described by referring to Figs . 1 and 2 is installed. For example, the electronic apparatus is 150 of FIG. 7 may be a communication apparatus such as a portable telephone in which the integrated circuit 10 is installed. A main CPU 152 controls function blocks in the electronic apparatus 150. A main memory 158 is used as a work area for the main CPU 152. A communication unit 156 is a function block implementing communication. In response to an instruction from the main CPU 152, the integrated circuit 10 executes processes related to a sound source such as sounding of a call incoming melody. The main CPU 152, the integrated circuit 10 and the communication unit 156 are connected to each other via the system bus 70.

In order for an instruction directed to an IP provided in the integrated circuit 10 to take effect, the only requirement is to write data in a common register regardless of whether the IP is implemented by hardware or software. The main CPU 152 is capable of giving an instruction for activation of a desired IP by writing data in a predetermined register regardless of the mode of implementation of IP in the integrated circuit 10. When the IP corresponding to the register in which data are written is implemented as a hardware IP, the hardware IP itself performs a required process. When the IP is not implemented as hardware, the internal CPU 56 of FIG. 2 inside the integrated circuit 10 runs a program so that software IP performs the process. When a software IP is responsible for the process, the integrated circuit 10 converts the instruction from the main CPU 152, i.e., the address and data on the system bus 70, into the address at which the program implementing the software IP is stored, and then runs the program.

For example, when the main CPU 152 writes the data in the register for generating a sound, the internal CPU 56 of FIG. 2 identifies the mode of implementation of the IP implementing that function by the method described already. If it is determined that the IP is implemented as a software IP, the integrated circuit 10 converts the instruction from the main CPU 152 into the address at which the program is stored, and then reads the program from that address. If the IP is implemented as a hardware IP, the hardware IP of the integrated circuit 10 performs the process. Thus, the integrated circuit 10 outputs a melody from a speaker 154. Since the main CPU 152 needs only to write data in a predetermined register regardless of the mode of implementation of IP in the integrated circuit 10, there should be provided only one control program to control the integrated circuit 10.

Second Embodiment

In the first embodiment, the integrated circuit 10 is described as having a CPU to replace some functions by software. By having a CPU, processes by hardware IPs and software IPs are performed within the confines of the integrated circuit so that the handling is made easy. In the second embodiment, the CPU is removed from the integrated circuit 10 so that the software IP is controlled by an external CPU.

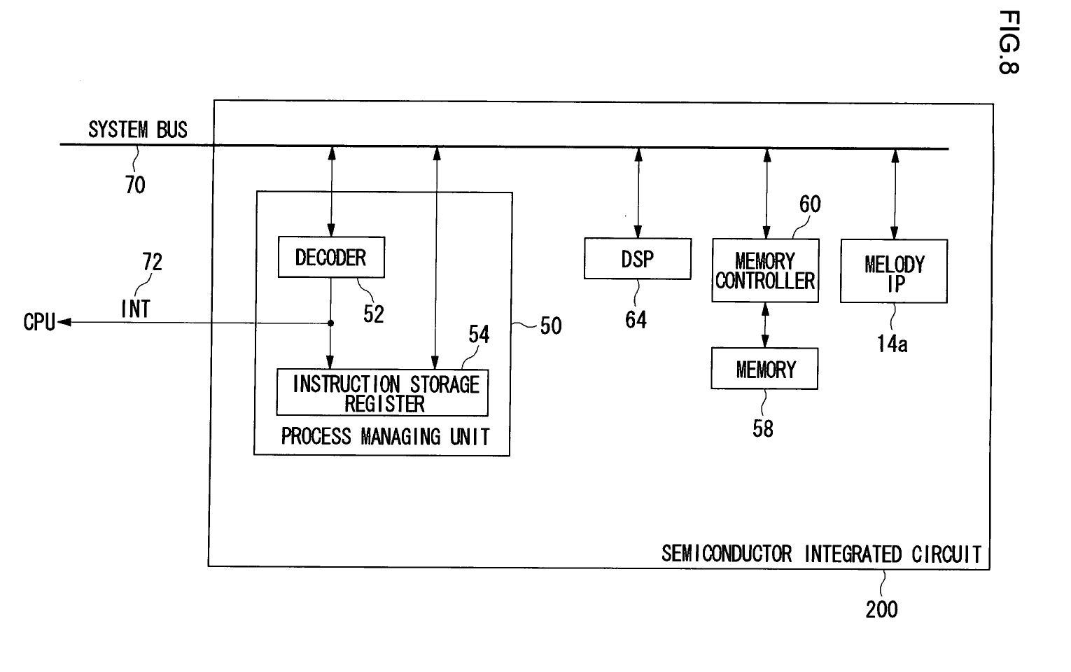

FIG. 8 shows an internal construction of an integrated circuit 200 according to the second embodiment. Components denoted by the same symbols as the components already explained have substantially the same function and operation as the components already explained. The following description mainly concerns a difference from the components already described. The integrated circuit 200 of FIG. 8 is installed, for example, in the electronic apparatus 150 of FIG. 7 in place of the integrated circuit 10. The integrated circuit 200 is connected to the main CPU 152 of FIG. 7 via the system bus 70 and controlled by the CPU 152. The memory 58 stores the first program 86, the second program 88, the table 82 and the availability information 84 of FIG. 4. The interrupt handler 80 and the work area 90 of FIG. 4 are stored in the main memory 158 of FIG. 7. When the integrated circuit 200 is installed in the electronic apparatus 150, the following matters are prescribed in the specification.

(1) The main CPU 152 is provided with a hardware construction which accepts the interrupt signal 72 from the integrated circuit 200.

(2) An interrupt handler corresponding to the interrupt signal 72 is implemented.

By designing the electronic apparatus 150 according to the specification as described above, the integrated circuit 200 is successfully built therein. Information regarding the interrupt handler etc. may be provided by the LSI manufacturer or originally developed by the set manufacturer. In an alternative example, the table 82 and the availability information 84 of FIG. 4 may be stored in the main memory 158. In this case, information relative to the table 82 and the availability information 84 is provided from the LSI manufacturer to the set manufacturer.

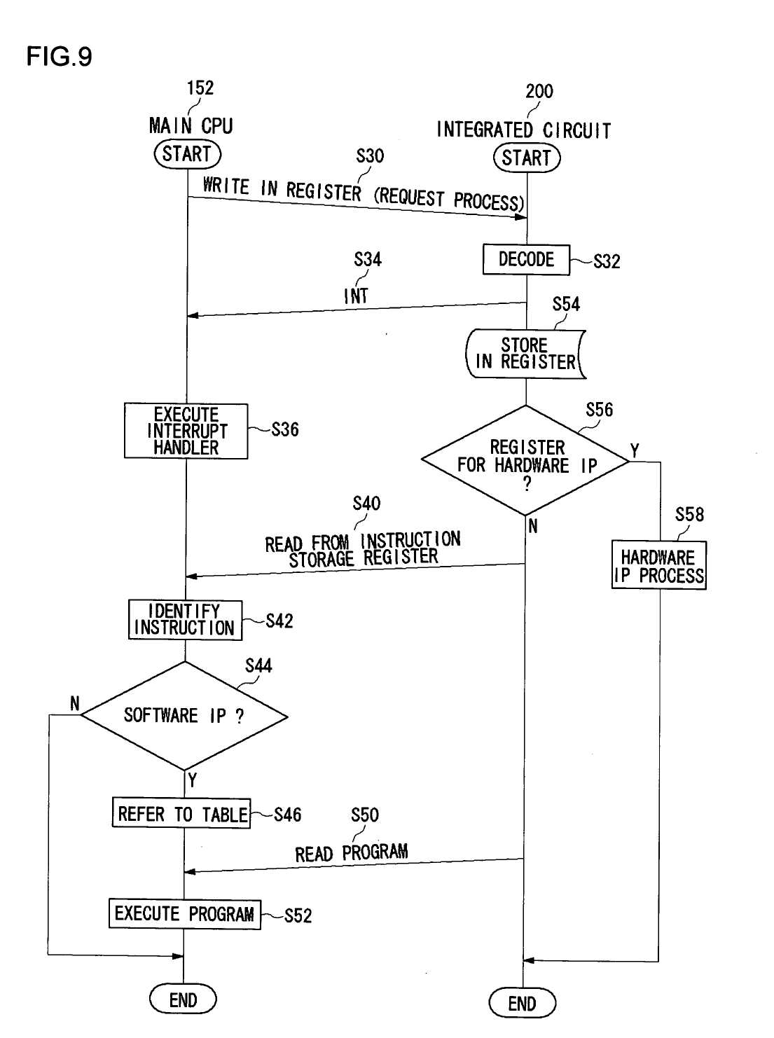

FIG. 9 shows a sequence of operation in the main CPU 152 and the integrated circuit 200 when the integrated circuit 200 of FIG. 8 is built into the electronic apparatus 150 of FIG. 7. The main CPU 152 of FIG. 7 writes in the register of a desired IP in the integrated circuit 200 of FIG. 8 (S30). The decoder 52 of the integrated circuit 200 outputs a hit signal to the instruction storage register 54 of FIG. 8 when the writing in the IP register in the integrated circuit 200 is detected (S32). The instruction storage register 54 stores the address and data on the system bus 70 when it receives the hit signal (S54). The decoder 52 outputs the hit signal as the interrupt signal 72 to the main CPU 152 (S34) The main CPU 152 runs the interrupt handler corresponding to the interrupt signal 72 (S36).

When the interrupt handler is run, the main CPU 152 reads the address and data stored in the instruction storage register 54 from the integrated circuit 200 (S40). More specifically, the main CPU 152 issues a read command to the system bus 70 and outputs an address of the instruction storage register 54. The main CPU 152 reads the address and data stored in the instruction storage register 54. The main CPU 152 identifies an IP to which the instruction is directed and also identifies the type of instruction, on the basis of the address and data thus read (S42). The main CPU 152 refers to the availability information 84 stored in the main memory 158 of FIG. 7 or the memory 58 of FIG. 8 so as to determine whether the IP to be activated in accordance with the instruction is a software IP (S44).

If the IP to be activated is a software IP (Y in S44), the main CPU 152 refers to the table 82 stored in the main memory 158 of FIG. 7 or the memory 58 of FIG. 8 so as to read the address at which the program implementing the software IP is stored (S46). The main CPU 152 sequentially reads the program from the address in the memory 58 of the integrated circuit 200 (S50). The main CPU 152 runs the program thus acquired (S52). With this, the software IP is activated using the main CPU 152.

When the IP to be activated is not a software IP (N in S44), the main CPU 152 terminates the execution of the interrupt handler. When predetermined data are written in a register for activating a hardware IP (S56), the hardware IP performs the process (S56). Thus, by issuing an interrupt to the main CPU 152 of FIG. 7, the external CPU, when the address and data for a given IP in the integrated circuit 200 of FIG. 8 is detected, the interrupt handler is activated. When the main CPU 152 determines that the IP to be activated is implemented as a software IP as a result of running the interrupt handler, the main CPU 152 reads the program implementing the software IP from the memory 58 of the integrated circuit 200 and runs the program. When data are written in a register for a hardware IP, the hardware IP implemented in the integrated circuit 200 performs the process independently of the interrupt handler run by the main CPU 152.

When the integrated circuit 200 of FIG. 8 is installed in the electronic apparatus 150 of FIG. 7, the main CPU 152 of FIG. 7 need only write data in a predetermined register regardless of the mode of implementation of IP in the integrated circuit 200 so that only one control program is necessary to control the integrated circuit 200. By utilizing the main CPU 152 of the electronic apparatus 150 to activate software IPs, the cost of the integrated circuit 200 is reduced. By improving the performance of the main CPU 152, the load imposed by the program implementing the software IP on the main CPU 152 is reduced.

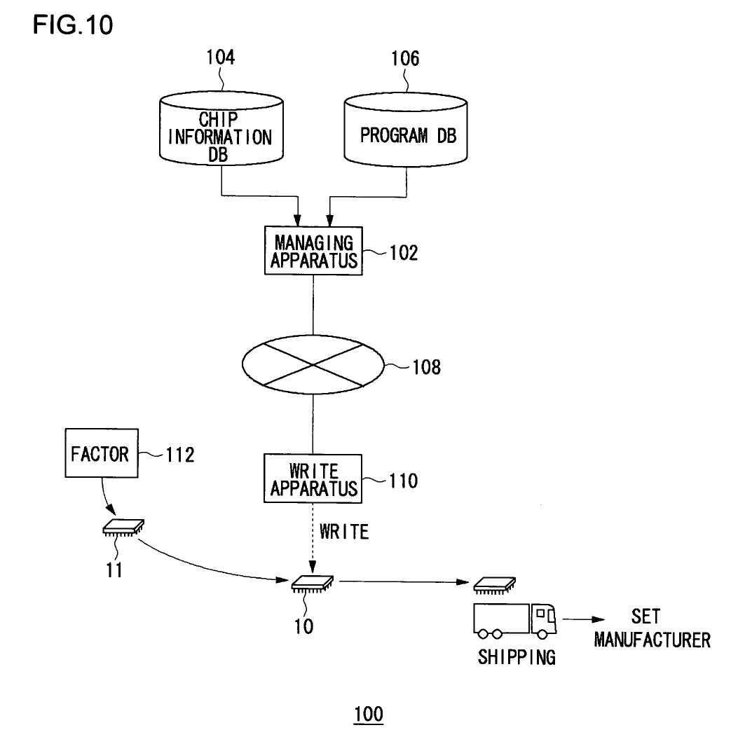

FIG. 10 shows an overall work flow observed before the integrated circuit 10 of FIG. 2 or the integrated circuit 200 of FIG. 8 is shipped. Since the shipping of the integrated circuit 10 of FIG. 2 is substantially the same as that of the integrated circuit 200 of FIG. 8, the following description will focus the integrated circuit 10 of FIG. 2. A factory 112 manufactures a pre-fabrication integrated circuit 11. The pre-integrated circuit 11 is the integrated circuit 10 of FIG. 2 in which programs are not stored yet. The pre-fabrication integrated circuit 11 has the main function unit 14 but does not have any functions in the sub-function unit 16, i.e. does not store any programs. A write apparatus 110 writes a program adapted to requirements from the set manufacturer in the integrated circuit 11, thus completing the fabrication of the integrated circuit 10 for the set manufacturer specifically requesting that circuit. The integrated circuit 10 thus fabricated is shipped to the set manufacturer. By writing programs before shipping, versatility of the integrated circuit 10 is improved and changes in design requested by the set manufacturer are flexibly dealt with.

A manufacturing system 100 of the integrated circuit 100 is provided with the write apparatus 110 for writing programs in the pre-fabricated integrated circuit 11 and a managing apparatus 102 for providing programs to the write apparatus 110. The write apparatus 110 is connected to the managing apparatus 102 via a network 108. A chip information database 104 stores terms of contract with the set manufacturer, i.e. information (hereinafter, referred to as function information) related to the functions to be installed in the integrated circuit 10. A program database 106 stores, for each CPU running a program, programs implementing software IPs. When writing a program in the pre-fabrication integrated circuit 11, the write apparatus 110 requests the managing apparatus 102 to supply a program to be stored in the integrated circuit 10 adapted to the set manufacturer to which the integrated circuit 10 is shipped. The managing apparatus 102 refers to the function information stored in the chip information database 104 and acquires the program corresponding to the function information from the program database 106. The function information includes information specifying a CPU installed in the integrated circuit 10. The managing apparatus 102 selects a program executable by the CPU. The managing apparatus 102 outputs the program to the write apparatus 110. In selecting a program to be stored in the integrated circuit 200 of FIG. 8, the function information includes information specifying an external CPU using the integrated circuit 200. The managing apparatus selects a program executable by the specified external CPU.

The write apparatus 110 writes the program supplied from the managing apparatus 102 in the pre-fabrication integrated circuit 11. This completes the fabrication of the integrated circuit 10. By storing programs before shipping, it is ensured that only necessary programs are stored. Accordingly, the license fee for unused hardware IPs is prevented from being incurred. Also, by reducing a period of time required for shipping, much contribution is done to the reduction in period of time required for development at the set manufacturer. When a need arises to remove a specific IP after writing programs in the integrated circuit 10, the write apparatus 110 deletes the program implementing that IP from the integrated circuit 10. Deletion may be done by the set manufacturer.

Described above is an explanation based on the embodiment. The embodiment of the present invention is only illustrative in nature and it will be obvious to those skilled in the art that various combinations of constituting elements and processes are possible within the scope of the present invention.

Correspondence between an constituting element of the present invention and that of the embodiment will be shown. A conversion process mechanism refers to a group of members comprising the instruction storage register 54, the internal CPU 54, and the table 82 of FIG. 4 stored in the memory 58.

1. An integrated circuit comprising:
a main function unit implementing by hardware predetermined functions selected from a group of functions provided by the integrated circuit;
a sub-function unit storing programs implementing functions other than the predetermined function by software; and
a process managing unit responding to an external instruction and activating a process at least using said sub-function unit, wherein
said process managing unit receives the instruction in the format which assumes that the sub-function unit is constructed of hardware.

2. The integrated circuit according to claim 1, further comprising a CPU, wherein said process managing unit activates said CPU when it is determined that the external instruction requires a process using said sub-function unit.

3. The integrated circuit according to claim 2, wherein said CPU converts the external instruction into address information and reads a program stored in said sub-function unit.

4. The integrated circuit according to claim 1, wherein said process managing unit activates an external unit so as to allow an external processing agent to execute the process using said sub-function unit.

5. The integrated circuit according to claim 1, wherein said main-function unit implements a melody function.

6. The integrated circuit according to claim 1, wherein said sub-function unit implements a surround function.

7. The integrated circuit according to claim 1, wherein said sub-unit function implements an equalizer function.

8. The integrated circuit according to claim 1, wherein said sub-unit function implements a bass sound enhancement function.

9. An integrated circuit comprising:
a main function unit implementing by hardware predetermined functions selected from a group of functions provided by the integrated circuit;
a sub-function unit storing programs implementing functions other than the predetermined function by software; and
a conversion process mechanism converting an external instruction into information for a predetermined processing agent to read a program stored in said sub-function unit, when the external instruction requires a process using said sub-function unit.

10. The integrated circuit according to claim 9, wherein the external instruction includes an instruction that directly operates hardware.

11. The integrated circuit according to claim 9, wherein said main-function unit implements a melody function.

12. The integrated circuit according to claim 9, wherein said sub-function unit implements a surround function.

13. The integrated circuit according to claim 9, wherein said sub-function unit implements an equalizer function.

14. The integrated circuit according to claim 9, wherein said sub-function unit implements a bass sound enhancement function.

15. An electronic apparatus comprising:
a main CPU implementing predetermined functions; and
an integrated circuit according to claim 1 under the control of said main CPU and executes a predetermined process in accordance with an instruction from said main CPU.

16. The electronic apparatus according to claim 15, wherein said integrated circuit further comprises a sub-CPU, and said process managing unit activates the sub-CPU when it is determined that the external instruction requires a process using said sub-function unit.

17. The electronic apparatus according to claim 16, wherein the sub-CPU converts the external instruction into address information and reads a program stored in said sub-function unit.

18. The electronic apparatus according to claim 15, wherein said process managing unit activates an external unit so as to allow an external processing agent to execute the process using said sub-function unit.
